(19) United States
(12) Patent Application Publication
(10) Pub. No.: US 2025/0246531 A1
(43) Pub. Date: Jul. 31, 2025

(54) INTEGRATED CIRCUIT (IC) PACKAGE WITH DIE INTERCONNECTS TERMINATING AT MULTIPLE METALLIZATION LAYERS IN A SUBSTRATE TO REDUCE SPACING REQUIREMENTS BETWEEN DIE INTERCONNECTS

(71) Applicant: QUALCOMM Incorporated, San Diego, CA (US)

(72) Inventors: Aniket Patil, San Diego, CA (US); Yangyang Sun, San Diego, CA (US); Joan Rey Villarba Buot, Escondido, CA (US)

(21) Appl. No.: 18/425,447

(22) Filed: Jan. 29, 2024

(51) Int. Cl. H01L 23/498; H01L 23/00; H01L 23/66; H01L 25/065

(52) U.S. Cl. CPC H01L 23/49838; H01L 23/49816; H01L 23/66; H01L 24/08; H01L 24/32; H01L 25/0657; H01L 2223/6616; H01L 2223/6677; H01L 2224/08146; H01L 2224/08165; H01L 2224/32146; H01L 2224/32157; H01L 2225/06517; H01L 2225/06541; H01L 2924/1421; H01L 2924/15311

(57) ABSTRACT

Aspects disclosed include an integrated circuit (IC) package with die interconnects of a semiconductor die terminating at multiple metallization layers in a substrate to reduce spacing requirement between die interconnects. The die comprises a first plurality of die interconnects and a second plurality of die interconnects. The substrate includes a first metallization layer adjacent to the die and a second metallization layer that is parallel to the first metallization layer such that the first metallization layer is between the die and second metallization layer. The first and second metallization layers each comprise a respective first plurality of metal pads and a second plurality of metal pads. The first plurality of die interconnects terminates to the first plurality of metal pads in the first metallization layer while the second plurality of die interconnects terminates to the second plurality of metal pads in the second metallization layer.

### BACKGROUND

### I. Field of the Disclosure

The field of this disclosure relates to the design and manufacture of integrated circuit (IC) packages.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that is mounted on and electrically coupled to a package substrate to provide physical support and an electrical interface to the die(s). The package substrate also includes one or more metallization layers that include metal interconnects (e.g., metal traces, metal lines) with vertical interconnect accesses (vias) coupling the metal interconnects together between adjacent metallization layers to provide electrical interfaces between the die(s). A metallization layer is an insulating layer of a dielectric material that includes a metal layer in which one or more metal lines or traces are formed and which may include metal interconnects (e.g., metal pads) for providing electrical connections.

The die(s) also includes one or more metallization layers that include metal interconnects (e.g., metal pads, metal traces, metal lines) coupled to exposed die interconnects. The die interconnects are metal bumps or metal pillars that can be coupled to an outer metallization layer of the package substrate to mechanically support the die and also provide electrical coupling of the die to the package substrate for signal routing. The package substrate also includes an outer metallization layer that includes metal interconnects (e.g., metal pads) coupled to external metal interconnects (e.g., ball grid array (BGA) interconnects, array of pillars, array of bumps, or, generally, die interconnects) to provide an external interface between the die(s) in the IC package. The external metal interconnects can also be coupled (e.g., soldered) to traces in a printed circuit board (PCB) to attach the package to the PCB and interface its die(s) with the circuitry of the PCB.

### SUMMARY

Aspects disclosed in the detailed description include an integrated circuit (IC) package with die interconnects of a semiconductor die (“die”) terminating at multiple metallization layers in a substrate to reduce spacing requirements between the die interconnects. The die comprises a first plurality of die interconnects and a second plurality of die interconnects. The substrate includes a first metallization layer adjacent to the die and a second metallization layer that is parallel to the first metallization layer such that the first metallization layer is between the die and second metallization layer. The first and second metallization layers each comprise a respective first plurality of metal pads and a second plurality of metal pads. The first plurality of die interconnects terminates to the first plurality of metal pads in the first metallization layer while the second plurality of die interconnects terminates to the second plurality of metal pads in the second metallization layer. In this regard, the spacing requirements of adjacent die interconnects are reduced by terminating one die interconnect to a metal pad at a different metallization layer than an adjacent die interconnect allowing the IC package to support higher pin density dies without having to increase the size of the IC package. Additionally, by reducing the spacing requirements between die interconnects, more metal may be deployed for the die interconnects, thus, lowering direct current (DC) resistance and lowering alternating current (AC) impedance.

In this regard in one aspect, an integrated circuit (IC) package, comprising a die comprising a plurality of die interconnects which includes a first plurality of die interconnects and a second plurality of die interconnects. The IC package further comprising a substrate which comprises a first metallization layer extending in a first direction, the first metallization layer comprising a first plurality of metal pads and a second metallization layer extending in the first direction and parallel to the first metallization layer, the second metallization layer comprising a second plurality of metal pads. The first plurality of die interconnects extend in a second direction orthogonal to the first direction and terminate at the first plurality of metal pads, and the second plurality of die interconnects extend in the second direction and terminate at the second plurality of metal pads.

In another aspect, a method for fabricating an integrated circuit (IC) package to reduce spacing requirements between die interconnects includes providing a die comprising a plurality of die interconnects. The plurality of die interconnects comprises a first plurality of die interconnects and a second plurality of die interconnects. The method further includes forming a substrate which includes forming a first metallization layer extending in a first direction, the first metallization layer comprising a first plurality of metal pads and forming a second metallization layer extending in the first direction and parallel to the first metallization layer, the second metallization layer comprising a second plurality of metal pads. The method further includes coupling the first plurality of die interconnects extending in a second direction orthogonal to the first direction to the first plurality of metal pads and coupling the second plurality of die interconnects extending in the second direction to the second plurality of metal pads.

### BRIEF DESCRIPTION OF THE DRAWINGS

FIG. 1A is a top view of a portion of an exemplary substrate of an integrated circuit (IC) package having an array of metal pads coupled to power or ground nodes where the metal pads are deployed on one metallization layer;

FIG. 1B is a close-up view of cut out A1 from FIG. 1A;

FIG. 2A is a side view of a portion of an exemplary integrated circuit (IC) package including a die and a substrate where die interconnects of the die terminate at multiple metallization layers of the substrate to reduce spacing requirements between the die interconnects;

FIG. 2B is a side view of a portion of another exemplary IC package including a die and a substrate where die interconnects of the die terminate at multiple metallization layers of the substrate to reduce spacing requirements between the die interconnects;

FIG. 2C is a side view of a portion of another exemplary IC package including a die and a substrate where die interconnects of the die terminate at multiple metallization layers of the substrate to reduce spacing requirements between the die interconnects;

FIG. 3A is a top view of the exemplary substrate shown in FIG. 2A of metallization layer M1;

FIG. 3B is a top view of the exemplary substrate shown in FIG. 2A of metallization layer M2;

FIG. 4 is a flowchart illustrating an exemplary fabrication process of fabricating an IC package including a die and a substrate where die interconnects of the die terminate at multiple metallization layers of the substrate to reduce spacing requirements between the die interconnects including, but not limited to, the exemplary IC packages in FIGS. 2A-2C;

FIGS. 5A-5C is a flowchart illustrating an exemplary fabrication process of fabricating a substrate, wherein the substrate includes metal pads at multiple metallization layers to reduce spacing requirements between die interconnects including, but not limited to, the exemplary substrate in FIGS. 2A-2C;

FIGS. 6A-6F are exemplary fabrication stages during fabrication of the substrate according to the fabrication process in FIGS. 5A-5C;

FIGS. 7A-7E is a flowchart illustrating an exemplary fabrication process of fabricating a die having multiple length die interconnects to reduce spacing requirements between the die interconnects in a substrate, including, but not limited to, the exemplary die in FIGS. 2A-2C;

FIGS. 8A-8I are exemplary fabrication stages during fabrication of the die according to the fabrication process in FIGS. 7A-7E;

FIG. 9 is a flowchart illustrating an exemplary assembly process for assembling a die having multiple length die interconnects with a substrate having metal pads at multiple metallization layers to form an IC package to reduce spacing requirements between the die interconnection in the substrate, including, but not limited to, the exemplary IC packages in FIGS. 2A-2C;

FIGS. 10A-10B are exemplary fabrication stages during fabrication of the IC package according to the assembly process in FIG. 9;

FIG. 11 is a block diagram of an exemplary wireless communications device that includes radio-frequency (RF) components deployed in an IC package, wherein the IC package includes a die having multiple length die interconnects with a substrate having metal pads at multiple metallization layers to reduce spacing requirements between the die interconnects in the substrate, including, but limited to, the exemplary IC packages in FIGS. 2A-2C and according to the exemplary processes in FIGS. 4, 5A-5C, 7A-7E, and 9; and

FIG. 12 is a block diagram of an exemplary processor-based system that can include components deployed in an IC package, wherein the IC package includes a die having multiple length die interconnects with a substrate having metal pads at multiple metallization layers to reduce spacing requirements between the die interconnects in the substrate, including, but not limited to, the exemplary IC packages in FIGS. 2A-2C and according to the exemplary processes in FIGS. 4, 5A-5C, 7A-7E, and 9.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

Aspects disclosed in the detailed description include an integrated circuit (IC) package with die interconnects of a semiconductor die (“die”) terminating at multiple metallization layers in a substrate to reduce spacing requirements between the die interconnects. The die comprises a first plurality of die interconnects and a second plurality of die interconnects. The substrate includes a first metallization layer adjacent to the die and a second metallization layer that is parallel to the first metallization layer such that the first metallization layer is between the die and second metallization layer. The first and second metallization layers each comprise a respective first plurality of metal pads and a second plurality of metal pads. The first plurality of die interconnects terminate to the first plurality of metal pads in the first metallization layer while the second plurality of die interconnects terminate to the second plurality of metal pads in the second metallization layer. In this regard, the spacing requirements of a particular metal pad are reduced by terminating a die interconnect to an adjacent metal pad at a different metallization layer because the spacing requirements that are conventionally imposed in one metallization layer is accomplished in a vertical direction between two metallization layers. As an example, by reducing the spacing requirements between adjacent metal pads, more metal may be deployed for the die interconnects, thus, lowering direct current (DC) resistance and lowering alternating current (AC) impedance. Additionally, die interconnect pitch may be reduced by reducing the spacing requirements between adjacent metal pads allowing the IC package to support higher pin density dies without having to increase the size of the IC package.

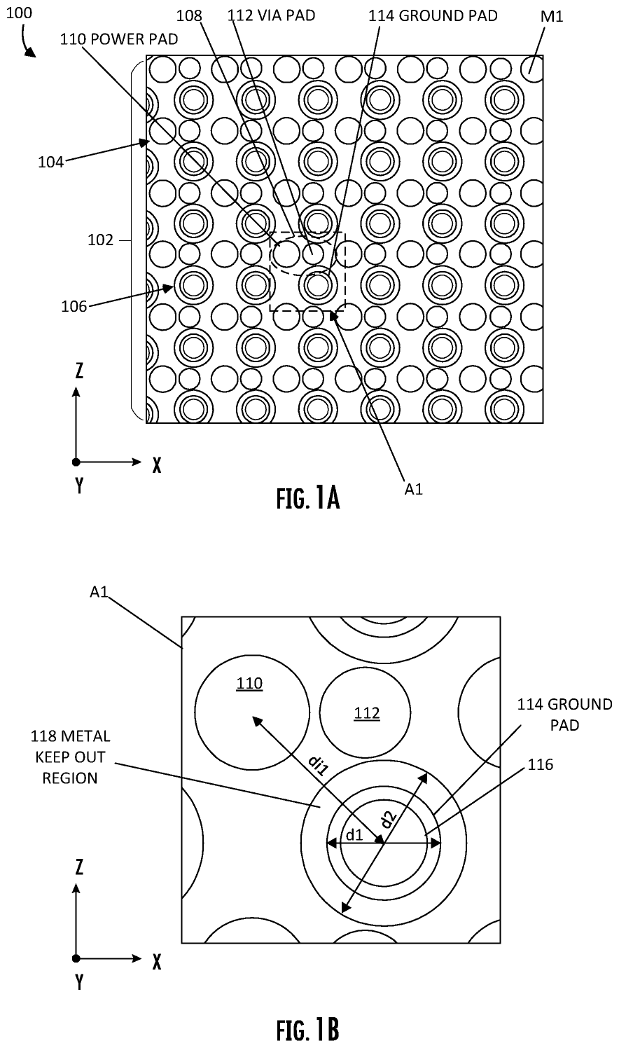

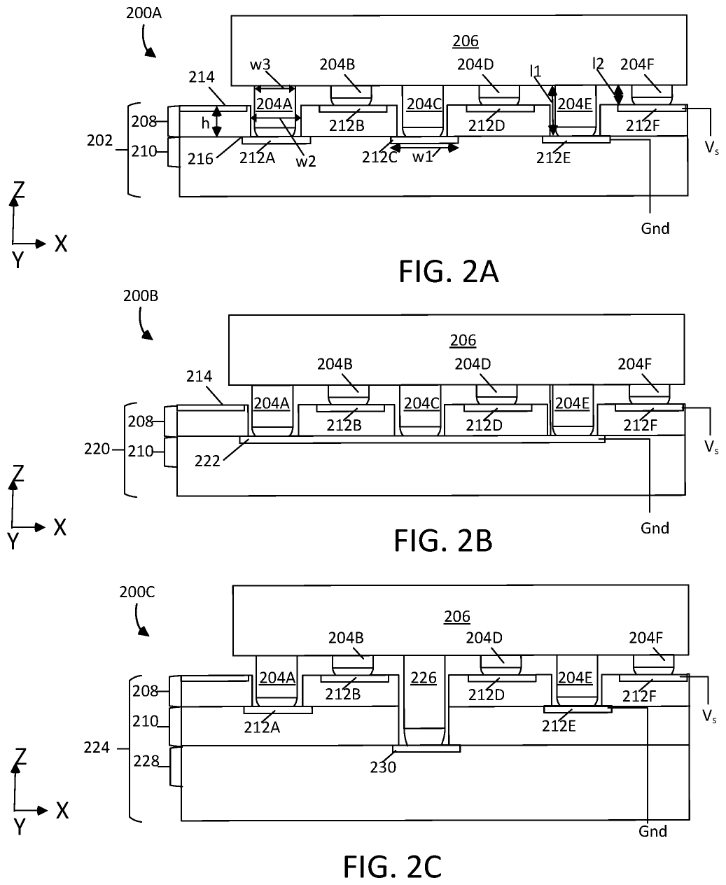

Before discussing exemplary aspects starting at FIG. 2A, a conventional substrate is discussed in FIGS. 1A and 1B. In this regard, FIG. 1A is a top view of a portion of an exemplary substrate 100 having an array of metal pads 102 coupled to power or ground nodes where the metal pads are deployed on one metallization layer, metallization layer M1. The array of metal pads 102 includes rows of power and via pad pairs 104 and rows of ground pads 106. A power and via pad pair 108 includes a power pad 110 and a via pad 112 which routes power to lower metallization layers that are not shown. A ground pad 114 is one of the ground pads which is next to the via pad pair 108 which is also illustrated in FIG. 1B, which is a close-up view of cut out A1 from FIG. 1A. The ground pad 114 includes an inner periphery 116 which reflects the outer periphery of a die interconnect. For this example, the ground pad 114 has a diameter, d1, which is 95 micrometers (μm). To prevent electrical shorts between the power and via pad pair 108 and the ground pad 114, a metal keep out region 118 surrounding the ground pad 114 is required. The metal keep out region 118 has a diameter, d2, of 139 μm. The metal keep out region 118 limits the distance, di1, between the center of the power pad 110 and the center of the ground pad 114, also known as a pitch of metal pads or “bump pitch,” on the substrate 100. The distance, di1, can range between 130 μm and 180 μm depending on the accuracy of substrate fabrication tools.

To decrease the pitch of metal pads in a given area of a substrate, FIGS. 2A-2C illustrate three embodiments of substrates which employ power and via pads on different metallization layers than ground pads. FIG. 2A is a side view of a portion of an exemplary IC package 200A including a substrate 202 where die interconnects 204A-204F of a die 206 terminate at multiple metallization layers of the substrate 202 to reduce spacing requirements between the die interconnects 204A-204F. The die 206 includes the die interconnects 204A-204F to couple internal circuitry of the die 206 to the substrate 202. In this example, die interconnects 204A, 204C, and 204E are connected to electrical ground while die interconnects 204B, 204D, and 204F are connected to a power node. The substrate 202 includes a first metallization layer 208, also referred to as metallization layer M1 (i.e., an M1 layer), and a second metallization layer 210, also referred to as metallization layer M2 (i.e., an M2 layer). The first metallization layer 208 extends in a first, horizontal direction (X-, Y-axes directions) and includes metal pads 212B, 212D, and 212F. The second metallization layer 210 also extends in the first, horizontal direction and is parallel to the first metallization layer 208. The second metallization layer 210 includes metal pads 212A, 212C, and 212E (e.g. copper pads, aluminum pads). The die interconnects 204B, 204D, and 204F extend in a second, vertical direction (Z-axis direction) orthogonal to the first direction (X-, Y-axes directions) and terminate at the metal pads 212B, 212D, and 212F, respectively. The die interconnects 204A, 204C, and 204E extend in the second direction (Z-axis direction) orthogonal to the first direction (X-, Y-axes directions) and terminate at the metal pads 212A, 212C, and 212E, respectively. The first metallization layer 208 includes a surface 214, and the second metallization layer 210 includes a surface 216. The die interconnects 204A, 204C, and 204E have a length, l1, extending in the second direction. The die interconnects 204B, 204D, and 204F have a length, l2, extending in the second direction. A distance, h, between the surface 214 of metallization layer 208 and the surface 216 of metallization layer 210 is substantially equal to the length, l1, minus the length, l2. In this example, widths, w1, in the X-axis direction of the metal pads 212A-212F are 95 μm. A width, w3, of space in the X-axis direction in the first metallization layer 208 to receive the die interconnects 204A, 204C, and 204E is less than 90 μm. A width, w2, of the die interconnects 204A, 204C, and 204E in the X-axis direction of the die interconnects 204A-204F is 32 μm. In contrast to the metal keep out region 118 in the X-, Y-axes directions in FIG. 1B, the distance, h, between the metallization layers 208 and 210 in the Z-axis direction is utilized as a metal keep out region to avoid electrical shorts between metal pads at different metallization layers. Terminating die interconnects at multiple metallization layers reduces the spacing requirements between pads in the X-, Y-axes directions.

FIG. 2B is a side view of a portion of another exemplary IC package 200B including a substrate 220 where the die interconnects 204A-204F of the die 206 terminate at multiple metallization layers 208, 210 of the substrate 220 to reduce spacing requirements between the die interconnects 204A-204F. Common elements between the IC package 200A in FIG. 2A and elements of the IC package 200B in FIG. 2B are shown with common element numbers. The second metallization layer 210 in FIG. 2B includes a ground node 222 to which the die interconnects 204A, 204C, and 204E terminate. The ground node 222 can be formed from connected metal pads 212A, 212C, and 212E.

FIG. 2C is a side view of a portion of another exemplary IC package 200C including a substrate 224 where the die interconnects 204A, 204B, 204D, 204E, 204F, and a die interconnect 226 of the die 206 terminate at multiple metallization layers of the substrate 224 to reduce spacing requirements between the die interconnects 204A, 204B, 204D, 204E, 204F, 226. Common elements between the IC package 200A in FIG. 2A and elements of the IC package 200C in FIG. 2C are shown with common element numbers. The substrate 224 includes a third metallization layer 228 which includes a metal pad 230. The die interconnect 226 terminates at the metal pad 230 at the third metallization layer 228. In this exemplary embodiment, the die interconnects 204A, 204B, 204D, 204E, 204F, 226 terminate at three different metallization layers 208, 210, 228.

For simplicity, FIGS. 2A-2C do not illustrate additional metallization layers that may exist in the substrates 202, 220, and 224. Also, FIGS. 2A-2C do not illustrate power via pads due to the perspective shown and would be found in the Y-axis direction behind the metal pads 212B, 212D, and 212F. Additionally, the embodiments described in FIGS. 2A-2C can be deployed on either a core substrate (where a pre-preg material is already cured at the time of fabricating the metallization layers on the substrate) or a coreless substrate (cure the substrate as the metallization layers are fabricated). Furthermore, although the embodiments described in FIGS. 2A-2C were described with die interconnects that carry power or are coupled to a ground node, the aspects described are also applicable to die interconnects that carry signals. The die 206 may include a system on a chip (SoC) or an active device including an inductor or capacitor.

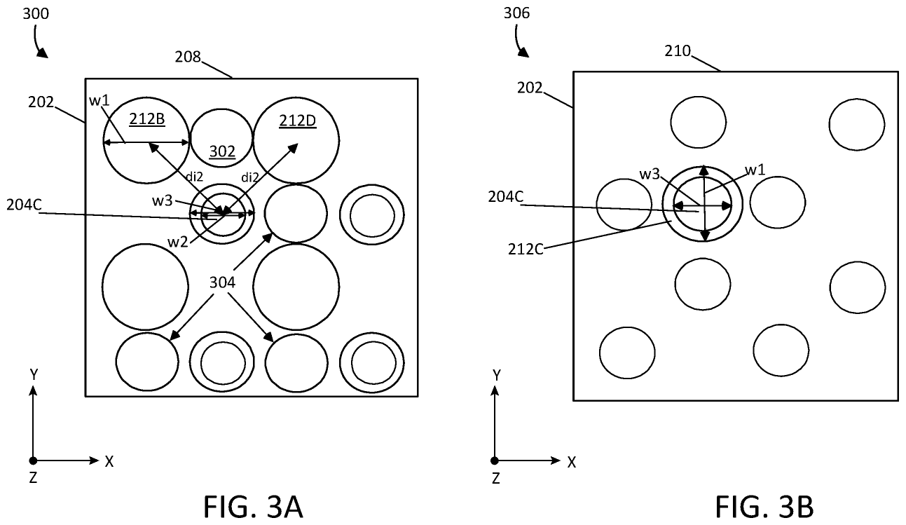

FIGS. 3A-3B are top views of a portion of the metallization layers 208 and 210, respectively, of the IC package 200A in FIG. 2A to illustrate a decrease in pitch and to enable additional arrangements of distributing power/via pad pairs on one metallization layer along with ground pads formed in another metallization layer. FIG. 3A is a top view 300 of a portion of the exemplary substrate 202 shown in FIG. 2A of the first metallization layer 208 (M1 layer). The elements illustrated in FIG. 2A are shown in FIG. 3A. In particular, the metal pads 212B and 212D and the die interconnect 204C are shown in the top view 300. Additionally, a via pad 302 which is paired with the metal pad 212B to route power carried in the metal pad 212B to other metallization layers in the substrate 202. Other via pads 304 are also shown. The metallization layers 208 and 210 (shown in FIG. 3B) include an arrangement of metal pads formed in the second metallization layer 210 whose nearest neighbor in the X-, Y-axes directions is either a metal pad or a via pad formed in the first metallization layer 208. The distance, di2, in the X-, Y-axes directions between either the metal pad 212B or 212D and the center of the die interconnect 204C which passes through the M1 metallization layer can be in a range between 90 μm and 120 μm depending on the accuracy of substrate fabrication tools. As such, the center of the die interconnect 204C has as a nearest neighbor in the horizontal direction (X-, Y-axes directions) the metal pad 212B to which the die interconnect 204B is terminated. From a die interconnect perspective, the first plurality of die interconnects 204B, 204D, 204F that terminate to the first metallization layer 208 are interleaved between the second plurality of die interconnects 204A, 204C, 204E that terminate at the second metallization layer 210 so that each of the second plurality of die interconnects 204A, 204C, 204E have at least one of the first plurality of die interconnects 204B, 204D, 204F as nearest neighbors in the horizontal direction. Since there is no metal keep out region such as the metal keep out region 118 in FIG. 1B, a designer is free to increase the radial size of die interconnects that terminate at the M1 metallization layer to decrease DC resistance and/or AC inductance.

FIG. 3B is a top view 306 of the exemplary substrate 202 shown in FIG. 2A of the second metallization layer 210 (M2 layer). Since the die interconnects 204B and 204D terminate at the first metallization layer 208, they do not have a footprint on the second metallization layer 210.

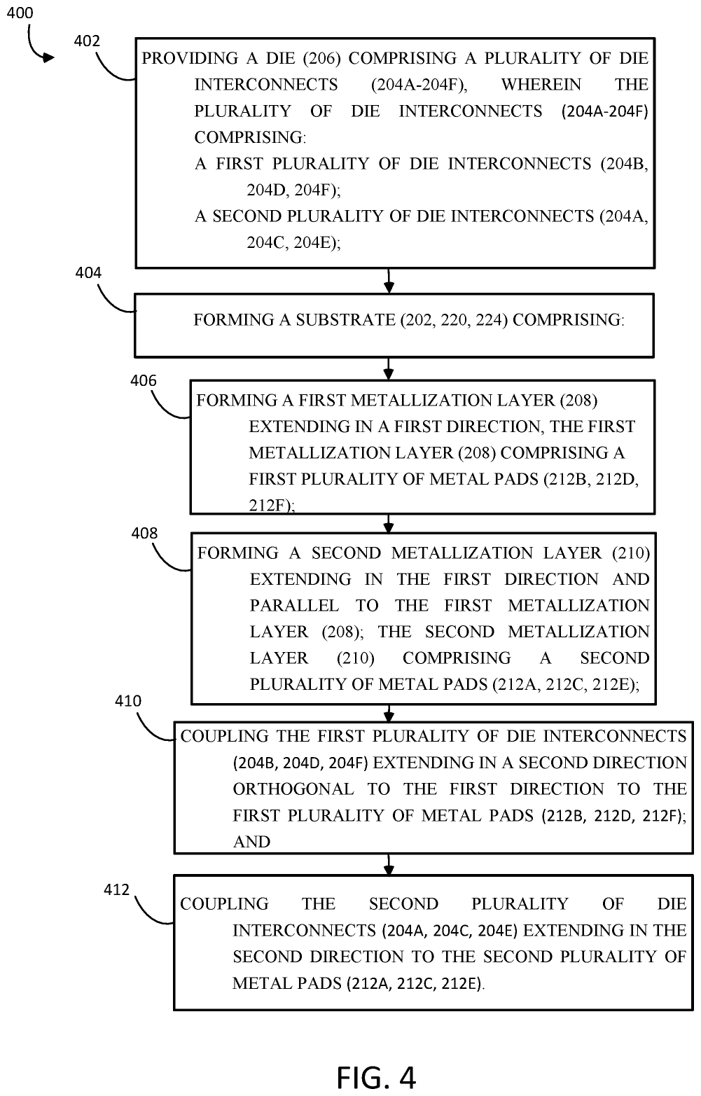

An IC package including a die and a substrate where die interconnects of the die terminate at multiple metallization layers of the substrate to reduce spacing requirements between the die interconnects, including, but not limited to, the exemplary IC packages in FIGS. 2A-2C can be fabricated by different fabrication processes. FIG. 4 is a flowchart illustrating an exemplary fabrication process 400 of fabricating an IC package including a die and a substrate where die interconnects of the die terminate at multiple metallization layers of the substrate to reduce spacing requirements between the die interconnects including, but not limited to, the exemplary IC packages in FIGS. 2A-2C.

In this regard, a first exemplary step in the fabrication process 400 of FIG. 4 can include providing a die 206 comprising a plurality of die interconnects 204A-204F, wherein the plurality of die interconnects 204A-204F comprises a first plurality of die interconnects 204B, 204D, and 204F, and a second plurality of die interconnects 204A, 204C, and 204E (block 402 in FIG. 4). A next step in the fabrication process 400 can include forming a substrate 202, 220, 224 (block 404 in FIG. 4). The fabrication process 400 of forming the substrate 202, 220, 224 includes the following two steps. One step includes forming a first metallization layer 208 extending in a first direction, the first metallization layer 208 comprising a first plurality of metal pads 212B, 212D, 212F (block 406 in FIG. 4). The other step in the fabrication process 400 of forming the substrate 202, 220, 224 can include forming a second metallization layer 210 extending in the first direction and parallel to the first metallization layer 208, the second metallization layer 210 comprising a second plurality of metal pads 212A, 212C, 212D (block 408 in FIG. 4).

The next step in the fabrication process 400 can include coupling the first plurality of die interconnects 204B, 204D, and 204F extending in a second direction orthogonal to the first direction to and terminating at the first plurality of metal pads 212B, 212D, and 212F (block 410 in FIG. 4). The next step in the fabrication process 400 can include coupling the second plurality of die interconnects 204A, 204C, and 204E extending in the second direction orthogonal to the first direction to and terminating at the first plurality of metal pads 212A, 212C and 212E (block 412 in FIG. 4).

The steps of forming the die 206, forming the substrate 202, 220, and 224 and coupling the die 206 to the substrate 202, 220, and 2204 may be performed by three different companies, respectively.

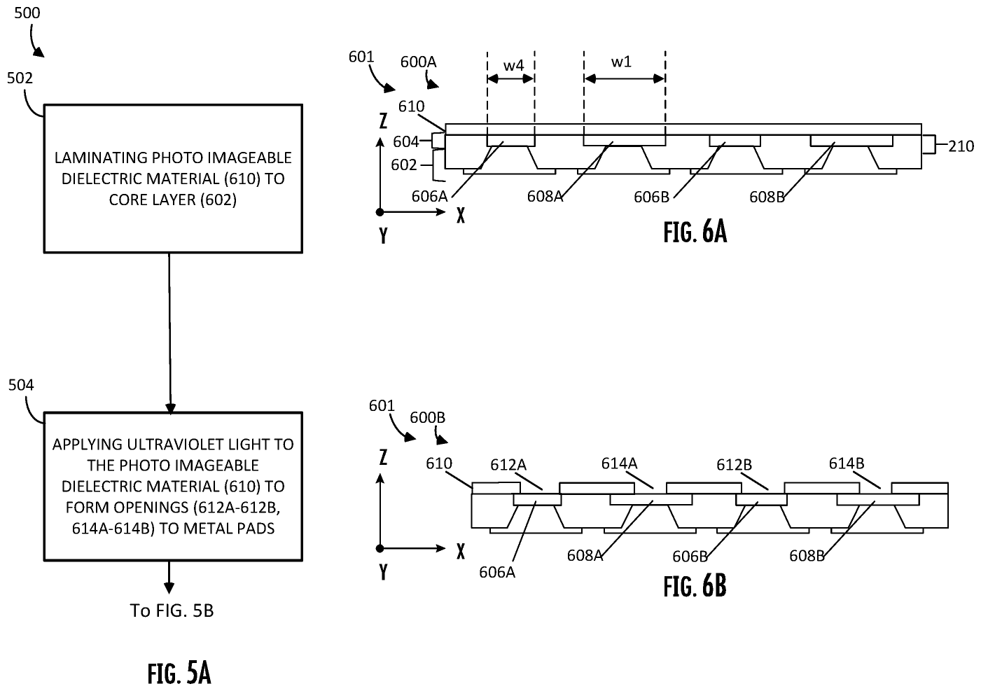

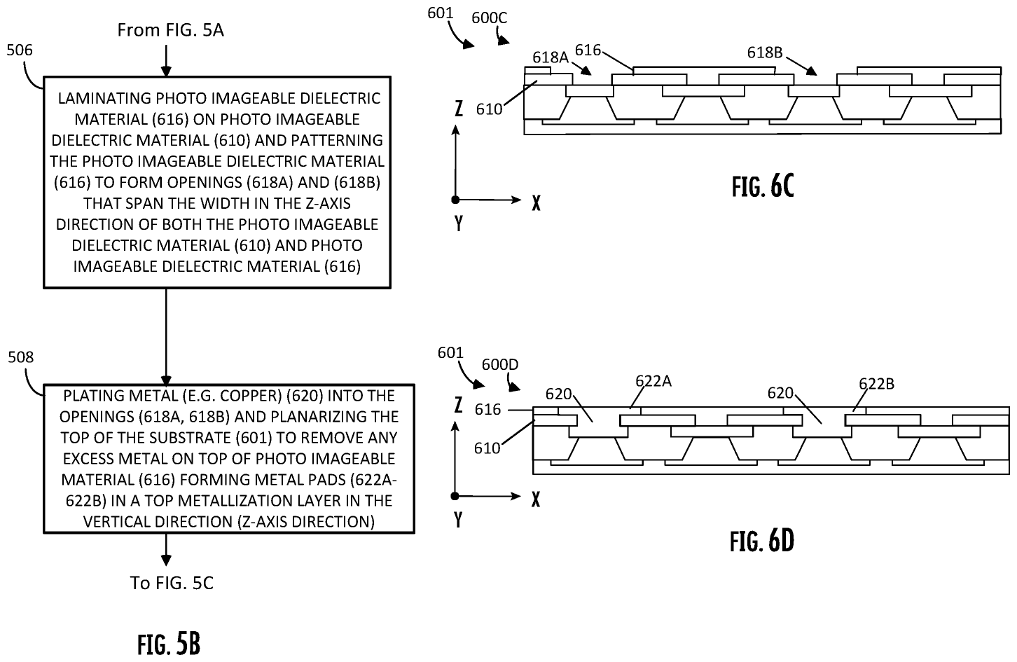

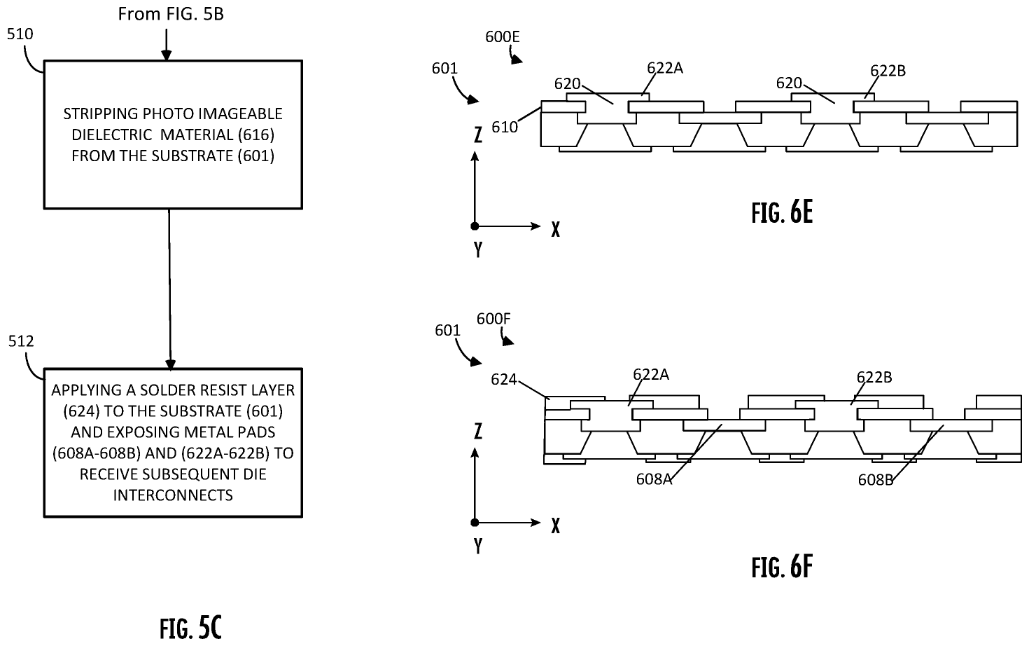

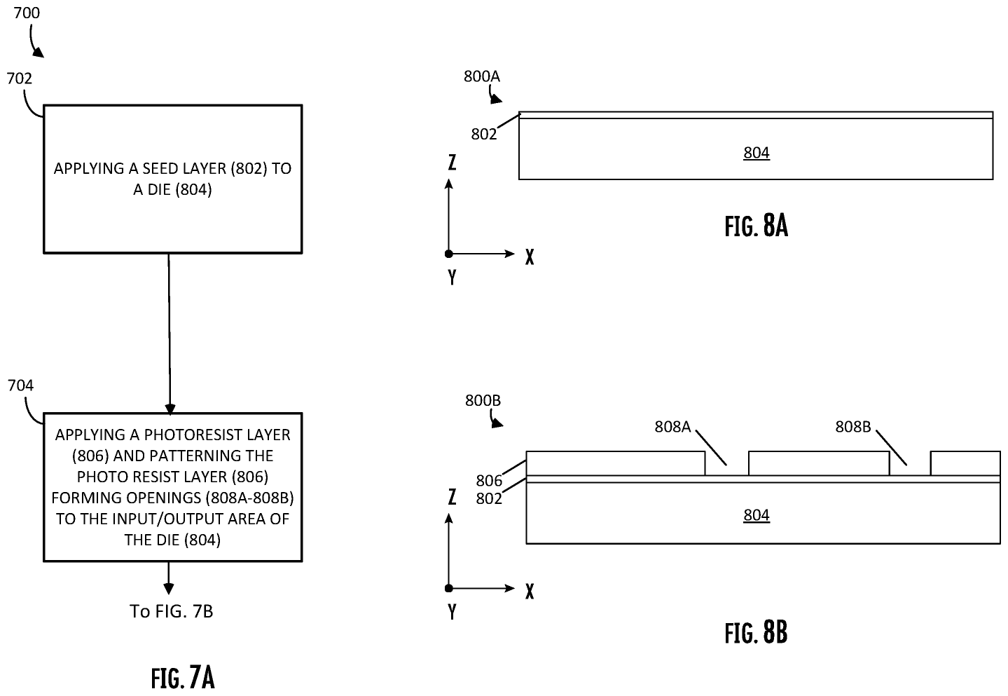

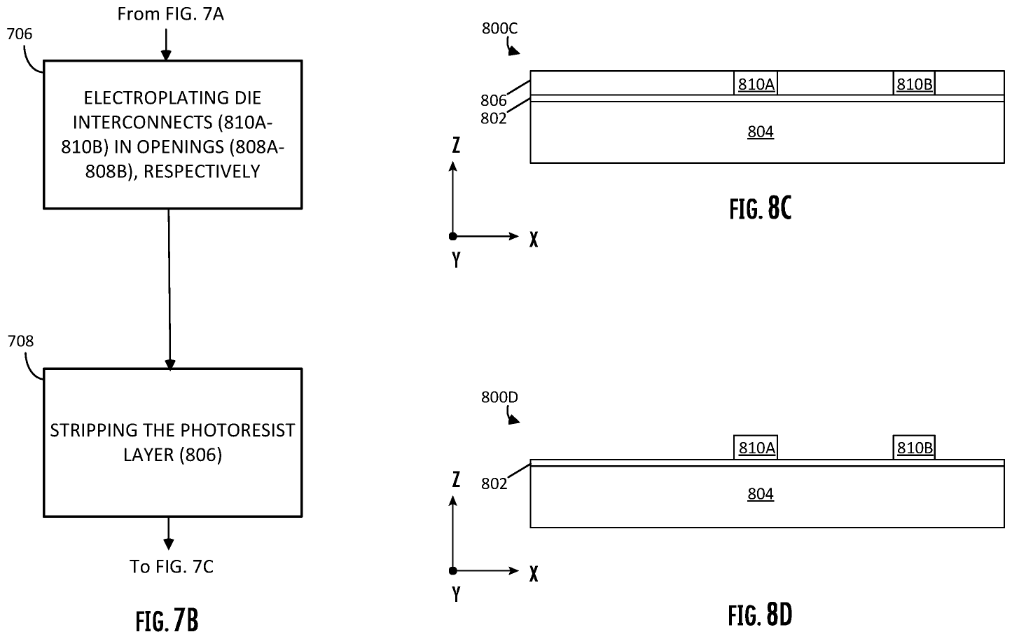

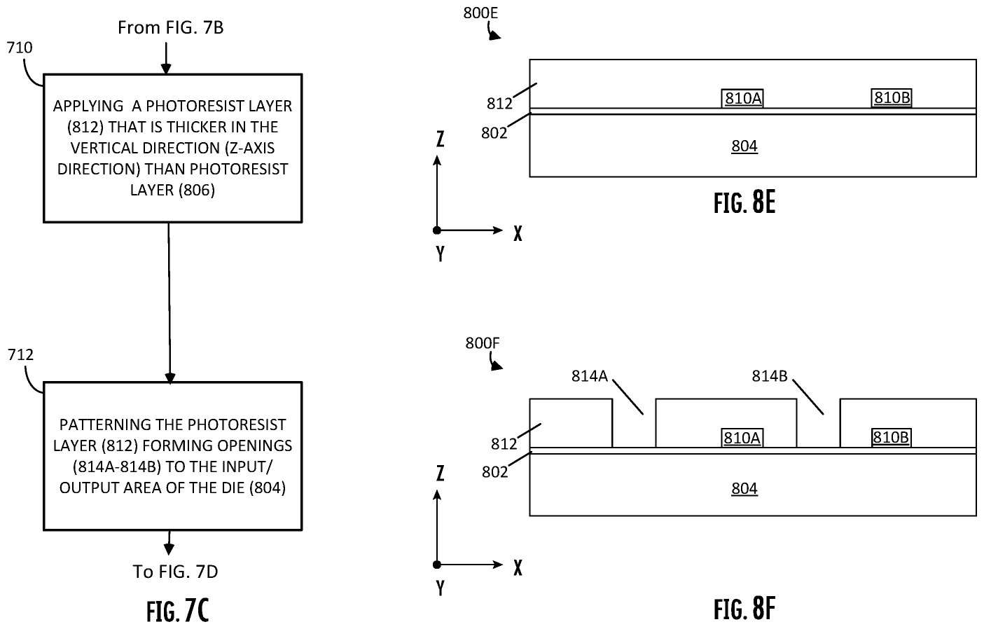

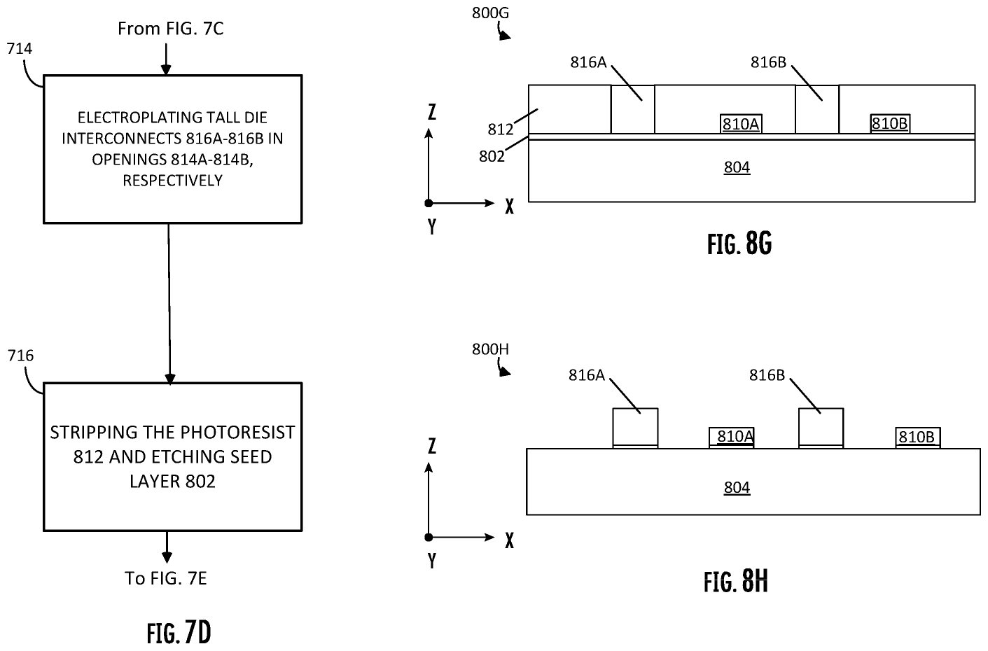

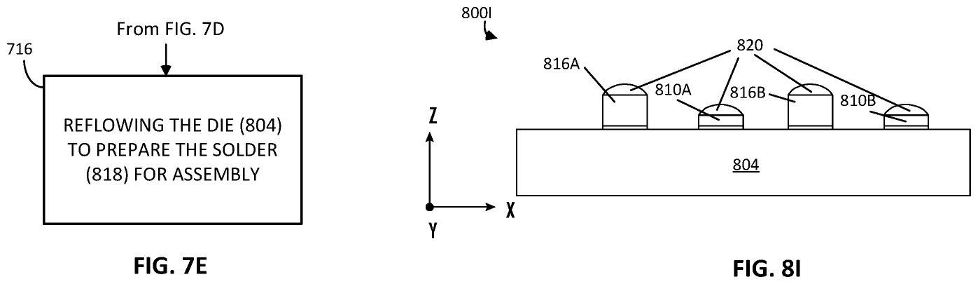

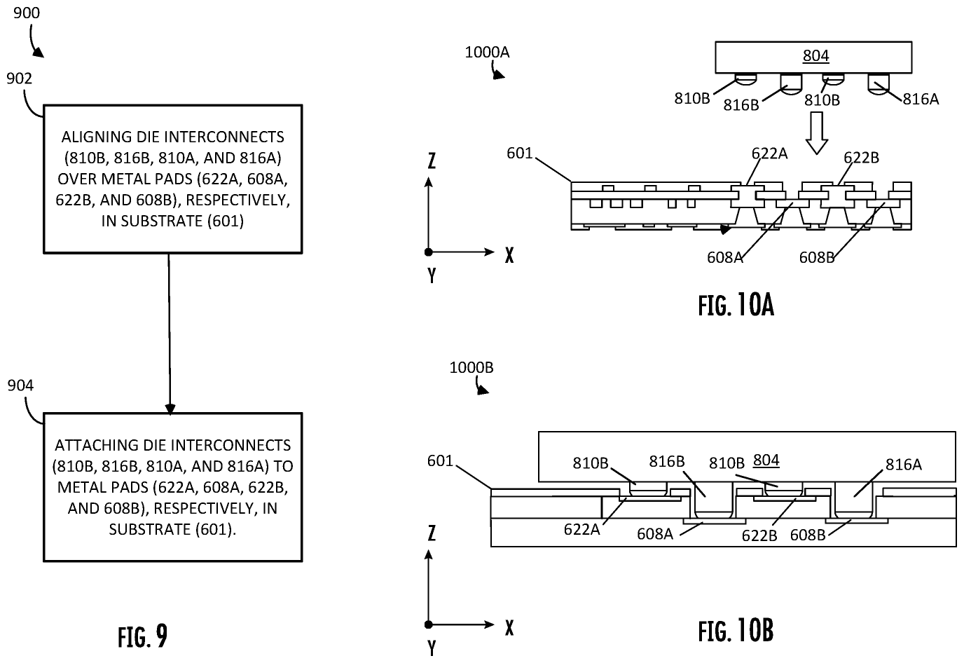

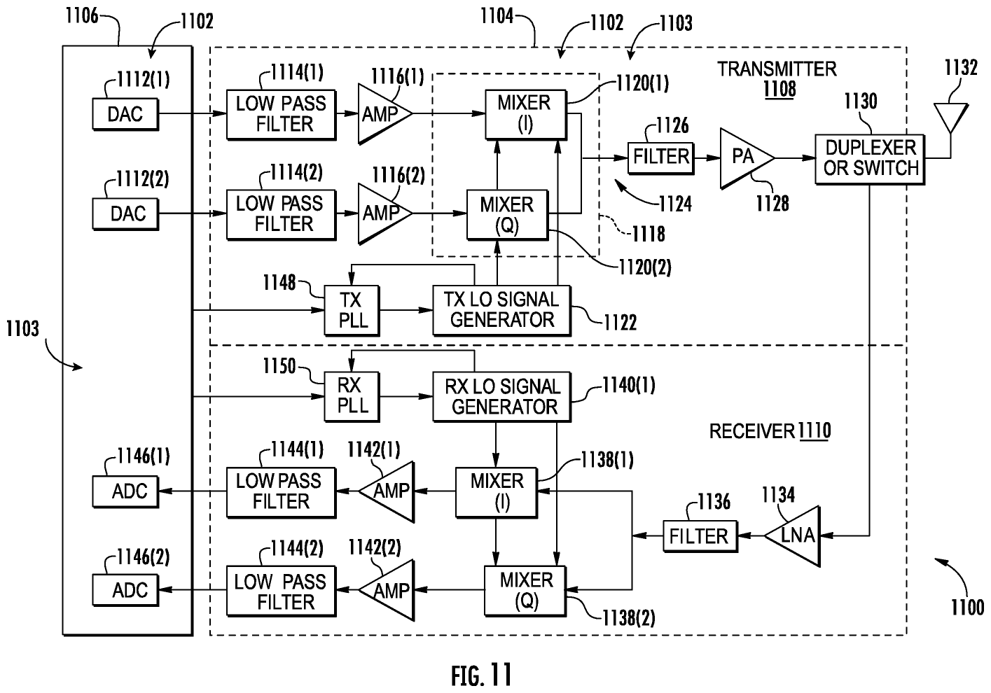

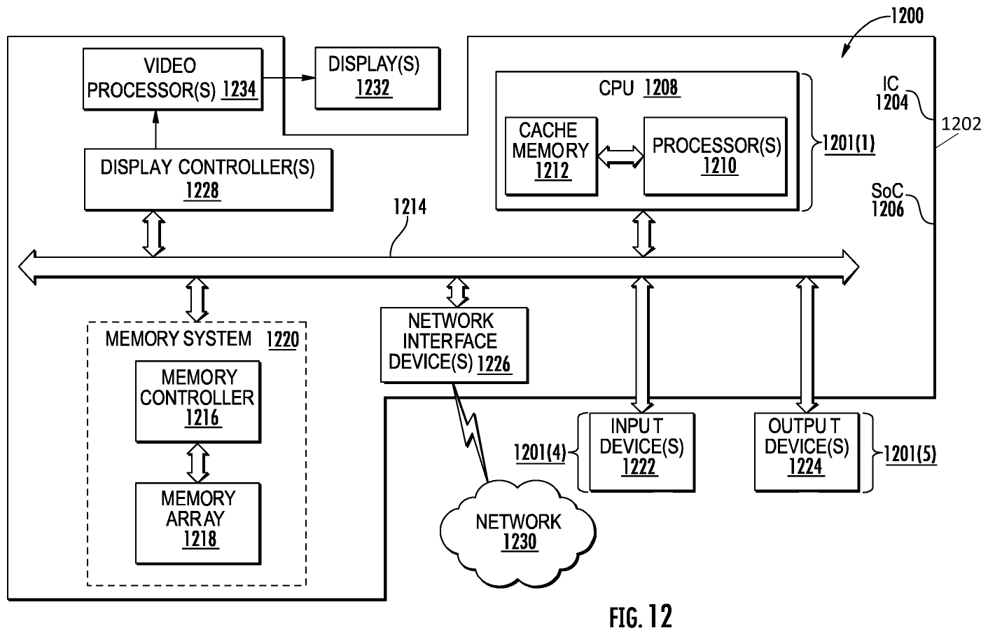

FIGS. 5A-5C is a flowchart illustrating an exemplary fabrication process 500 of fabricating a substrate deployed in an IC package, including, but not limited to, the IC packages 200A-200C in FIGS. 2A-2C, where die interconnects of a die terminate at multiple metallization layers of the substrate to reduce spacing requirements between the die interconnects. FIGS. 6A-6F are exemplary fabrication stages 600A-600F during fabrication of the substrate according to the fabrication process 500 in FIGS. 5A-5C. The fabrication process 500 as shown in the fabrication stages 600A-600F in FIGS. 6A-6F are in reference to an exemplary substrate which can terminate die interconnects at two metallization layers to reduce spacing requirements between the die interconnects. Fabricating a die 206 with various length die interconnects will be discussed in connection with FIGS. 7A-7E and 8A-8I. Assembling the die and the substrate to form the IC package 200A will be described in connection with FIGS. 9 and 10A-10B.

Fabrication stages 600A-600F in FIGS. 6A-6F utilize an embedded trace substrate 601. The embedded trace substrate 601 includes a core layer 602 and an embedded metallization layer 604 including metal interconnects fabricated in the substrate 601. The metallization layer 604 (e.g., M2 layer) includes via pads 606A and 606B and metal pads 608A and 608B which can be used to terminate a ground connection. The via pads 606A and 606B have a width, w4, which is less than the width, w1, of the metal pads 608A and 608B. In this regard, as shown in fabrication stage 600A in FIG. 6A, an exemplary step in the fabrication process 500 is laminating a photo imageable dielectric material 610 to the core layer 602 (block 502 in FIG. 5A). As shown in fabrication stage 600B in FIG. 6B, a next step in the fabrication process 500 can include applying ultraviolet light to the photo imageable dielectric material 610 to form openings 612A, 614A, 612B, and 614B to the metal pads 606A, 608A, 606B, and 608B, respectively (block 504 in FIG. 5A). As shown at fabrication stage 600C in FIG. 6C, a next step in the fabrication process 500 can include laminating a photo imageable dielectric material 616 on the photo imageable dielectric material 610 and patterning the photo imageable dielectric material 616 to form openings 618A and 618B that span the width in the vertical direction (Z-axis direction) of both the photo imageable dielectric material 610 and the photo imageable dielectric material 616 (also referred to as a two-level opening) (block 506 in FIG. 5A). The portion of the openings 618A and 618B that spans the width in the vertical direction (Z-axis direction) of the photo imageable dielectric layer 616 are aligned with the portion of the openings 618A and 618B that spans the width in the vertical direction (Z-axis direction) of the photo imageable dielectric material 610, respectively, to provide an opening large enough to subsequently receive a die interconnect. As shown at fabrication stage 600D in FIG. 6D, a next step in the fabrication process 500 can include plating metal (e.g., copper) 620 into the openings 618A and 618B and planarizing the top of the substrate to remove excess metal on top of photo imageable dielectric material 616 and forming metal pads 622A-622B in a top metallization layer in the vertical direction (Z-axis direction) (block 508 in FIG. 5B). As shown at fabrication stage 600E in FIG. 6E, a next step in the fabrication process 500 can include stripping the photo imageable dielectric material 616 from the substrate 601 (block 510 in FIG. 5C). As shown at fabrication stage 600F in FIG. 6F, a next step in the fabrication process 500 can include applying a solder resist layer 624 to the substrate 601 and exposing the metal pads 608A-608B and 622A-622B to receive subsequent die interconnects (block 512 in FIG. 5C). To create more than two metallization layers to receive die interconnects, blocks 502-510 may be repeated for each additional metallization layer.

FIGS. 7A-7E is a flowchart illustrating an exemplary fabrication process 700 of fabricating an exemplary die having multiple length die interconnects to reduce spacing requirements between the die interconnects in a substrate, including, but not limited to, the exemplary die in FIGS. 2A-2C. FIGS. 8A-8I are exemplary fabrication stages 800A-800I during fabrication of the die according to the fabrication process 700 in FIGS. 7A-7E. The exemplary fabrication process 700 will be discussed as a die level process but would apply to a wafer level process which includes a plurality of dies therein.

In this regard, as shown in fabrication stage 800A in FIG. 8A, an exemplary step in the fabrication process 700 includes applying a seed layer 802 to a die 804 (block 702 in FIG. 7A). As shown in fabrication stage 800B in FIG. 8B, a next step in the fabrication process 700 can include applying a photoresist layer 806 and patterning the photoresist layer 806 forming openings 808A-808B to the input/output area of the die 804 (block 704 in FIG. 7A). As shown at fabrication stage 800C in FIG. 8C, a next step in the fabrication process 700 can include electroplating die interconnects 810A-810B in the openings 808A-808B, respectively (block 706 in FIG. 7B). As shown at fabrication stage 800D in FIG. 8D, a next step in the fabrication process 700 can include stripping the photoresist layer 806 (block 708 in FIG. 7B). As shown at fabrication stage 800E in FIG. 8E, a next step in the fabrication process 700 can include applying a photoresist layer 812 that is thicker in the vertical direction (Z-axis direction) than the photoresist layer 806 (block 710 in FIG. 7C). As shown at fabrication stage 800F in FIG. 8F, a next step in the fabrication process 700 can include patterning the photoresist layer 812 forming openings 814A-814B to the input/output area of the die 804 (block 712 in FIG. 7C). As shown at fabrication stage 800G in FIG. 8G, a next step in the fabrication process 700 can include electroplating tall die interconnects 816A-816B in the openings 814A-814B, respectively (block 714 in FIG. 7D). As shown at fabrication stage 800H in FIG. 8H, a next step in the fabrication process 700 can include stripping the photoresist layer 812 and etching the seed layer 802 (block 716 in FIG. 7D). As shown at fabrication stage 8001 in FIG. 8I, a next step in the fabrication process 700 can include reflowing the die 804 to prepare the bumps/pillars for assembly (block 718 in FIG. 7E). To create more than two different length die interconnects to couple to more than two metallization layers in a substrate, blocks 710-716 may be repeated for each additional length die interconnect.

FIG. 9 is a flowchart illustrating an exemplary assembly process 900 for assembling a die having multiple length die interconnects with a substrate having metal pads at multiple metallization layers to form an IC package to reduce spacing requirements between the die interconnects in the substrate, including, but not limited to, the exemplary IC packages in FIGS. 2A-2C. FIGS. 10A-10B are exemplary fabrication stages during fabrication of the IC package according to the assembly process 900 in FIG. 9. In this regard, FIG. 9 and FIGS. 10A-10B will be discussed with regard to the substrate 601 after the fabrication stage 600F in FIG. 6F and the die 804 after the fabrication stage 8001 in FIG. 8I.

As shown in fabrication stage 1000A in FIG. 10A, an exemplary step in the assembly process 900 includes aligning the die interconnects 810B, 816B, 810A, and 816A over the metal pads 622A, 608A, 622B, and 608B, respectively, in the substrate 601 (block 902 in FIG. 9). As shown at fabrication stage 1000B in FIG. 10B, a next step in the assembly process 900 can include attaching the die interconnects 810B, 816B, 810A, and 816A to the metal pads 622A, 608A, 622B, and 608B, respectively, in substrate 601 (block 904 in FIG. 9).

Electronic devices that include an IC package, wherein the IC package includes a die and a substrate where die interconnects of the die terminate at multiple metallization layers of the substrate to reduce spacing requirements between the die interconnects including, but not limited to, the exemplary IC packages in FIGS. 2A-2C and according to, but not limited to, the exemplary fabrication and assembly processes in FIGS. 4, 5A-5C, 7A-7E, and 9 and according to any exemplary aspects disclosed herein may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

In this regard, FIG. 11 illustrates an exemplary wireless communications device 1100 that includes radio-frequency (RF) components formed from one or more ICs 1102, wherein any of the ICs 1102 can be deployed in an IC package 1103 wherein the IC package 1103 includes a die and a substrate where die interconnects of the die terminate at multiple metallization layers of the substrate to reduce spacing requirements between the die interconnects including, but not limited to, the exemplary IC packages in FIGS. 2A-2C and according to the exemplary fabrication and assembly processes in FIGS. 4, 5A-5C, 7A-7E, and 9 and according to any exemplary aspects disclosed herein. The wireless communications device 1100 may include or be provided in any of the above-referenced devices, as examples. As shown in FIG. 11, the wireless communications device 1100 includes a transceiver 1104 and a data processor 1106. The data processor 1106 may include a memory to store data and program codes. The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals (e.g., I and Q output currents) for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency up-conversion as well as noise in a receive frequency band. A power amplifier (PA) 1128 amplifies the upconverted signal 1124 from the filter 1126 to obtain the desired output power level and provides a transmit RF signal. The transmit RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Down-conversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by AMPs 1142(1), 1142(2) and further filtered by lowpass filters 1144(1), 1144(2) to obtain I and Q analog input signals, which are provided to the data processor 1106. In this example, the data processor 1106 includes analog-to-digital converters (ADCs) 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency up-conversion, while the RX LO signal generator 1140 generates the I and Q RX LO signals used for frequency down-conversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

FIG. 12 is a block diagram of an exemplary processor-based system 1200 that can include components deployed in an IC package, wherein the IC package includes a die and a substrate where die interconnects of the die terminate at multiple metallization layers of the substrate to reduce spacing requirements between the die interconnects including, but not limited to, the exemplary IC packages in FIGS. 2A-2C and according to, but not limited to, the exemplary fabrication and assembly processes in FIGS. 4, 5A-5C, 7A-7E, and 9 and according to any exemplary aspects disclosed herein. In this example, the processor-based system 1200 may be formed as an IC package 1202 such as the IC packages 200A-200C in FIGS. 2A-2C. The processor-based system 1200 includes a central processing unit (CPU) 1208 that includes one or more processors 1210, which may also be referred to as CPU cores or processor cores. The CPU 1208 may have cache memory 1212 coupled to the CPU 1208 for rapid access to temporarily stored data. The CPU 1208 is coupled to a system bus 1214 and can intercouple master and slave devices included in the processor-based system 1200. As is well known, the CPU 1208 communicates with these other devices by exchanging address, control, and data information over the system bus 1214. For example, the CPU 1208 can communicate bus transaction requests to a memory controller 1216, as an example of a slave device. Although not illustrated in FIG. 12, multiple system buses 1214 could be provided, wherein each system bus 1214 constitutes a different fabric.

Other master and slave devices can be connected to the system bus 1214. As illustrated in FIG. 12, these devices can include a memory system 1220 that includes the memory controller 1216 and a memory array(s) 1218, one or more input devices 1222, one or more output devices 1224, one or more network interface devices 1226, and one or more display controllers 1228, as examples. Each of the memory system(s) 1220, the one or more input devices 1222, the one or more output devices 1224, the one or more network interface devices 1226, and the one or more display controllers 1228 can be provided in the same or different electronic devices. The input device(s) 1222 can include any type of input device, including, but not limited to, input keys, switches, voice processors, etc. The output device(s) 1224 can include any type of output device, including, but not limited to, audio, video, other visual indicators, etc. The network interface device(s) 1226 can be any device configured to allow exchange of data to and from a network 1230. The network 1230 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1226 can be configured to support any type of communications protocol desired.

The CPU 1208 may also be configured to access the display controller(s) 1228 over the system bus 1214 to control information sent to one or more displays 1232. The display controller(s) 1228 sends information to the display(s) 1232 to be displayed via one or more video processor(s) 1234, which process the information to be displayed into a format suitable for the display(s) 1232. The display controller(s) 1228 and video processor(s) 1234 can be included as ICs in the same or different electronic devices, and in the same or different electronic devices containing the CPU 1208, as an example. The display(s) 1232 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. An integrated circuit (IC) package, comprising:
   a die comprising a plurality of die interconnects, the plurality of die interconnects comprising:
      a first plurality of die interconnects; and
      a second plurality of die interconnects; and
   a substrate comprising:
      a first metallization layer extending in a first direction, the first metallization layer comprising a first plurality of metal pads; and
      a second metallization layer extending in the first direction and parallel to the first metallization layer, the second metallization layer comprising a second plurality of metal pads,
      wherein the first plurality of die interconnects extend in a second direction orthogonal to the first direction and terminate at the first plurality of metal pads, and
      wherein the second plurality of die interconnects extend in the second direction and terminate at the second plurality of metal pads.
2. The IC package of clause 1, wherein the first metallization layer is an M1 layer.
3. The IC package of clause 1 or 2, wherein the second metallization layer is an M2 layer.
4. The IC package of any of clauses 1-3, wherein:
   the plurality of die interconnects further comprise:
      a third plurality of die interconnects;
   the substrate further comprises:
      a third metallization layer extending in the first direction and parallel to the second metallization layer, the third metallization layer comprising a third plurality of metal pads; and
   the third plurality of die interconnects extend in the second direction and terminate at the third plurality of metal pads.
5. The IC package of any of clauses 1-4, wherein:
   the first metallization layer is separated by a first distance in the second direction from the second metallization layer;
   the first plurality of die interconnects having a first length extending in the second direction;
   the second plurality of die interconnects have a second length extending in the second direction; and
   the second length minus the first length is substantially equal to the first distance.
6. The IC package of any of clauses 1-5, wherein:
   at least one of the second plurality of die interconnects has a nearest neighbor in the first direction which is at least one of the first plurality of die interconnects.
7. The IC package of any of clauses 1-6, wherein:
   the first plurality of die interconnects is interleaved between the second plurality of die interconnects so that each of the second plurality of die interconnects has at least one of the first plurality of die interconnects as a nearest neighbor in the first direction.
8. The IC package of any of clauses 1-7, wherein:
   the second plurality of metal pads are coupled to ground.
9. The IC package of any of clauses 1-8, wherein:
   the first plurality of metal pads is coupled to a power node.
10. The IC package of any of clauses 1-9, wherein:
   the second plurality of metal pads form a ground plane.
11. The IC package of any of clauses 1-10 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.
12. A method for fabricating an integrated circuit (IC) package to reduce spacing requirements between die interconnects, comprising:
   providing a die comprising a plurality of die interconnects, the plurality of die interconnects comprising:
      a first plurality of die interconnects; and
      a second plurality of die interconnects;
   forming a substrate, comprising:
      forming a first metallization layer extending in a first direction, the first metallization layer comprising a first plurality of metal pads; and
      forming a second metallization layer extending in the first direction and parallel to the first metallization layer, the second metallization layer comprising a second plurality of metal pads;
   coupling the first plurality of die interconnects extending in a second direction orthogonal to the first direction to the first plurality of metal pads; and
   coupling the second plurality of die interconnects extending in the second direction to the second plurality of metal pads.
13. The method of clause 12, wherein the first metallization layer is an M1 layer.
14. The method of clause 12 or 13, wherein the second metallization layer is an M2 layer.
15. The method of any of clauses 12-14, wherein:
   the plurality of die interconnects further comprise:
      a third plurality of die interconnects; and
   forming the substrate further comprises:
      forming a third metallization layer extending in the first direction and parallel to the second metallization layer; the third metallization layer comprising a third plurality of metal pads;
   further comprising:
      coupling the third plurality of die interconnects extending in the second direction and terminating at the third plurality of metal pads.
16. The method of any of clauses 12-15, wherein:
   the first metallization layer is separated by a first distance in the second direction from the second metallization layer;
   the first plurality of die interconnects having a first length extending in the second direction;
   the second plurality of die interconnects having a second length extending in the second direction, and
   the second length minus the first length is substantially equal to the first distance.
17. The method of any of clauses 12-16, wherein the second plurality of metal pads is coupled to a ground node.
18. The method of any of clauses 12-17, wherein the first plurality of metal pads is coupled to power node.
19. The method of any of clauses 12-18, wherein the second plurality of metal pads form a single ground plane.
20. The method of any of clauses 12-19, wherein forming the first metallization layer further comprises:
   patterning a first photo imageable dielectric material to form a plurality of first openings in the first photo imageable dielectric material; and
   laminating, in the first direction, a second photo imageable dielectric material on the first photo imageable dielectric material.
21. The method of clause 20, wherein forming the first metallization layer further comprises:
   patterning the second photo imageable dielectric material to form a plurality of second openings aligned with the plurality of first openings in the second direction, the plurality of first openings aligned with the plurality of second openings spanning, in the second direction, widths of the first photo imageable dielectric material and the second photo imageable dielectric material.

What is claimed is:

1. An integrated circuit (IC) package, comprising:
a die comprising a plurality of die interconnects, the plurality of die interconnects comprising:
a first plurality of die interconnects; and
a second plurality of die interconnects; and
a substrate comprising:
a first metallization layer extending in a first direction, the first metallization layer comprising a first plurality of metal pads; and
a second metallization layer extending in the first direction and parallel to the first metallization layer, the second metallization layer comprising a second plurality of metal pads,
wherein the first plurality of die interconnects extend in a second direction orthogonal to the first direction and terminate at the first plurality of metal pads, and
wherein the second plurality of die interconnects extend in the second direction and terminate at the second plurality of metal pads.

2. The IC package of claim 1, wherein the first metallization layer is an M1 layer.

3. The IC package of claim 1, wherein the second metallization layer is an M2 layer.

4. The IC package of claim 1, wherein:
the plurality of die interconnects further comprise:
a third plurality of die interconnects;
the substrate further comprises:
a third metallization layer extending in the first direction and parallel to the second metallization layer, the third metallization layer comprising a third plurality of metal pads; and
the third plurality of die interconnects extend in the second direction and terminate at the third plurality of metal pads.

5. The IC package of claim 1, wherein:
the first metallization layer is separated by a first distance in the second direction from the second metallization layer;
the first plurality of die interconnects having a first length extending in the second direction;
the second plurality of die interconnects have a second length extending in the second direction; and
the second length minus the first length is substantially equal to the first distance.

6. The IC package of claim 1, wherein:
at least one of the second plurality of die interconnects has a nearest neighbor in the first direction which is at least one of the first plurality of die interconnects.

7. The IC package of claim 1, wherein:
the first plurality of die interconnects is interleaved between the second plurality of die interconnects so that each of the second plurality of die interconnects has at least one of the first plurality of die interconnects as a nearest neighbor in the first direction.

8. The IC package of claim 1, wherein:
the second plurality of metal pads are coupled to ground.

9. The IC package of claim 1, wherein:
the first plurality of metal pads is coupled to a power node.

10. The IC package of claim 1, wherein:
the second plurality of metal pads form a ground plane.

11. The IC package of claim 1 integrated into a device selected from a group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics systems; and a multicopter.

12. A method for fabricating an integrated circuit (IC) package to reduce spacing requirements between die interconnects, comprising:
providing a die comprising a plurality of die interconnects, the plurality of die interconnects comprising:
a first plurality of die interconnects; and
a second plurality of die interconnects;
forming a substrate, comprising:
forming a first metallization layer extending in a first direction, the first metallization layer comprising a first plurality of metal pads; and
forming a second metallization layer extending in the first direction and parallel to the first metallization layer, the second metallization layer comprising a second plurality of metal pads;
coupling the first plurality of die interconnects extending in a second direction orthogonal to the first direction to the first plurality of metal pads; and
coupling the second plurality of die interconnects extending in the second direction to the second plurality of metal pads.

13. The method of claim 12, wherein the first metallization layer is an M1 layer.

14. The method of claim 12, wherein the second metallization layer is an M2 layer.

15. The method of claim 12, wherein:
the plurality of die interconnects further comprise:
a third plurality of die interconnects; and
forming the substrate further comprises:
forming a third metallization layer extending in the first direction and parallel to the second metallization layer; the third metallization layer comprising a third plurality of metal pads;
further comprising:
coupling the third plurality of die interconnects extending in the second direction and terminating at the third plurality of metal pads.

16. The method of claim 12, wherein:
the first metallization layer is separated by a first distance in the second direction from the second metallization layer;
the first plurality of die interconnects having a first length extending in the second direction;
the second plurality of die interconnects having a second length extending in the second direction, and
the second length minus the first length is substantially equal to the first distance.

17. The method of claim 12, wherein the second plurality of metal pads is coupled to a ground node.

18. The method of claim 12, wherein the first plurality of metal pads is coupled to power node.

19. The method of claim 12, wherein the second plurality of metal pads form a single ground plane.

20. The method of claim 12, wherein forming the first metallization layer further comprises:
patterning a first photo imageable dielectric material to form a plurality of first openings in the first photo imageable dielectric material; and
laminating, in the first direction, a second photo imageable dielectric material on the first photo imageable dielectric material.

21. The method of claim 20, wherein forming the first metallization layer further comprises:
patterning the second photo imageable dielectric material to form a plurality of second openings aligned with the plurality of first openings in the second direction, the plurality of first openings aligned with the plurality of second openings spanning, in the second direction, widths of the first photo imageable dielectric material and the second photo imageable dielectric material.
